(19) United States
(12) Patent Application Publication
(10) Pub. No.: US 2015/0048431 A1
(43) Pub. Date: Feb. 19, 2015

(54) METHOD FOR FORMING A CONTACT ON A SEMICONDUCTOR SUBSTRATE AND SEMICONDUCTOR DEVICE

(71) Applicant: ROBERT BOSCH GMBH, Stuttgart (DE)

(72) Inventors: Thomas Suenner, Stuttgart (DE); Michael Grieb, Leonberg (DE)

(73) Assignee: ROBERT BOSCH GMBH, Stuttgart, DE (DE)

(21) Appl. No.: 14/383,004

(22) PCT Filed: Jan. 29, 2013
(86) PCT No.: PCT/EP2013/051684

§ 371 Date: Sep. 4, 2014

(30) Foreign Application Priority Data
Mar. 5, 2012 (DE) 10 2012 203 443.9

(51) Int. Cl. H01L 29/417; H01L 21/04; H01L 29/16; H01L 21/3213; H01L 29/78; H01L 21/3205; H01L 21/321; H01L 29/66; H01L 29/45

(52) U.S. Cl. CPC H01L 29/41775; H01L 29/66068; H01L 21/0485; H01L 29/1608; H01L 29/45; H01L 29/78; H01L 21/32051; H01L 21/321; H01L 21/32135
USPC 257/288; 438/586

(57) ABSTRACT

A method for forming a contact on a semiconductor substrate includes: applying a metal to an exposed partial area of an outer side of the semiconductor substrate and/or of a layer applied to the semiconductor substrate, the partial area being surrounded by at least one edge region of an insulating layer, and the at least one edge region of the insulating layer being at least partially covered by the metal; heating the semiconductor substrate, whereby the metal which is applied to the exposed partial area reacts with at least one semiconductor material of the partial area to form a semiconductor-metal material as the end material or a further processing material of the at least one contact; and etching using an etching material having a higher etching rate for the metal than for the semiconductor-metal material.

### BACKGROUND OF THE INVENTION

1. Field of the Invention

The present invention relates to a method for forming a contact on a semiconductor substrate, and also relates to a semiconductor device.

2. Description of the Related Art

FIGS. 1a and 1b show schematic illustrations of a semiconductor device according to the related art.

The conventional semiconductor device shown schematically in FIGS 1a and 1b may be created with the aid of the method described in published German patent application document DE 10 2010 030 850 A1, for example. The semiconductor device includes a silicon carbide carrier 10, on whose top side a gate stack structure 12 and a plurality of conductive contacts 14 are formed.

FIG. 1b represents the inner composition of gate stack structure 12 with the aid of the cross section along line AA′ of FIG. 1a. In the shown exemplary embodiment, gate stack structure 12 includes a gate oxide layer 16, which is applied to the top side of silicon carbide carrier 10, a gate metallization layer 18, which at least partially covers gate oxide layer 16, and an insulating layer 20, which is applied to layers 16 and 18. Each of contacts 14 is electrically connected to gate stack structure 12 with the aid of implantations 22 through 26 having different concentrations. Moreover, each of contacts 14 is situated in an opening 28 in gate stack structure 12. The wet or dry chemical structuring of contacts 14 in openings 28 is possible according to the related art by maintaining a distance a0 in each case between an edge of each opening 28 and an edge of a lithography mask (not represented). Distance a0 is at least more than 20 nm, in most cases more than 50 nm, generally more than 100 nm. Distance a0 is comparatively large in relation to an expansion b of each contact 14 oriented parallel to the top side of silicon carbide carrier 10.

### BRIEF SUMMARY OF THE INVENTION

By carrying out the method according to the present invention, basically self-aligned contacts having no dedicated lithography plane are producible. Selectively, they may also be structured with a lithography plane having low requirements in regard to the alignment and low requirements in regard to the etching allowance.

The method is usable in particular for manufacturing the advantageous semiconductor device. The method is thus usable for implementing a relatively small distance of smaller than 10 nm between a gate stack structure and at least one contact. As a result of the ability to create a significantly reduced distance between the at least one contact and the gate stack structure, the semiconductor device may be implemented with a smaller expansion parallel to the substrate surface which is provided with at least one contact. Due to the material savings thus achieved, such as savings of the substrate material, the advantageous semiconductor device is less expensive to manufacture. Moreover, the ability to create the semiconductor device in a smaller design facilitates its transport, attachment and use. In addition, the implementation of a smaller distance between the at least one gate stack structure and the at least one contact may also be used for a higher cell concentration on an area of the substrate surface on which the contacts are implemented. In this case, the present invention is also usable for reducing an on-state resistance of a transistor.

In one advantageous specific embodiment of the method, at least one of the contacts is formed at a distance smaller than 10 nm from at least one gate stack structure. An alignment or etching allowance may thus be dispensed with in the embodiment of the method.

In one advantageous refinement of the method, at least one ion beam etching step may be carried out between the application of the at least one metal and the heating of the semiconductor substrate, in an etching direction which is inclined relative to an axis oriented perpendicularly to the outer side of the semiconductor substrate. In this way, coarse structuring of the at least one metal may be carried out prior to heating the semiconductor substrate, whereby it is preventable that the at least one metal reacts at undesirable points with the material of the semiconductor substrate, or with at least one substance applied thereto, during the heating process.

For example, nickel, titanium, aluminum, tantalum and/or tungsten may be applied as the at least one metal. The advantageous method is thus suitable for forming a plurality of contacts from various materials.

In particular, prior to the application of the at least one metal, the insulating layer may be formed on at least one partial outer side of the outer side of the semiconductor substrate and/or of the layer which is applied to the semiconductor substrate, and the at least one partial area of the outer side of the semiconductor substrate and/or of the layer which is applied to the semiconductor substrate may be exposed at at least one point of the at least one contact to be formed. For example, at least one silicon oxide layer and/or one silicon nitride layer may be formed as the insulating layer. In this way, cost-effective and easily processable materials may be used for the insulating layer.

At least one gate stack structure and/or at least one gate stack substructure may also be covered by the insulating layer. It is thus possible to reliably protect the covered component from coming in contact with the at least one metal during the heating process of the semiconductor substrate. Moreover, the insulating layer covering a gate stack substructure may be used as a subunit of the gate stack structure to complete the same. This multifunctionality of the insulating layer allows method steps and materials to be saved.

For example, the substrate may be heated to a temperature of at least 600° C. during the heating process. Such a method step is carried out easily and quickly with the aid of a furnace.

In one advantageous specific embodiment, an isotropic etching step is carried out as the etching step using the etching material having the higher etching rate for the at least one metal than for the semiconductor-metal material. It is thus possible to carry out the etching step easily and within a comparatively short time.

For example, at least one source contact is formed as the at least one contact. This is advantageous since, in particular in the case of a MOSFET, a smaller distance between each source contact and an adjoining gate stack structure is desirable. However, the ability to carry out the method described here is not limited to the manufacture of source contacts.

The above-described advantages are also assured with a corresponding semiconductor device.

In one advantageous specific embodiment, the distance between the at least one gate stack structure and at least one of the contacts is smaller than 5 nm. This allows a significant reduction of the expansion of the semiconductor device parallel to the substrate top side on which the contacts are implemented and/or a considerable increase in the cell concentration in one area.

In particular, the at least one contact may be surrounded by the at least one gate stack structure at a distance of smaller than 10 nm, in particular smaller than 5 nm. The semiconductor device may thus have a particularly advantageous arrangement of a plurality of contacts in openings of a gate stack structure.

The at least one contact may be a source contact. The advantageous semiconductor device may thus also be designed as a power semiconductor (MOSFET), in particular as a silicon carbide power semiconductor.

In the advantageous semiconductor device, the at least one contact may be surrounded by an insulating layer which at least partially covers the gate stack structure or a gate stack substructure, the insulating layer including residual traces of nickel, titanium, aluminum, tantalum and/or tungsten on its outer surface. With the aid of such residual traces, it is possible to detect that the semiconductor device is manufactured with the aid of the above-described advantageous method.

### BRIEF DESCRIPTION OF THE DRAWINGS

FIGS 1a and 1b show schematic illustrations of a semiconductor device according to the related art.

FIG. 2 shows a flow chart to illustrate a first specific embodiment of the method for forming a contact on a semiconductor substrate.

FIG. 3 shows a schematic cross section through a semiconductor substrate to explain a second specific embodiment of the method for forming a contact on a semiconductor substrate.

FIG. 4 shows a schematic top view onto one specific embodiment of the semiconductor device.

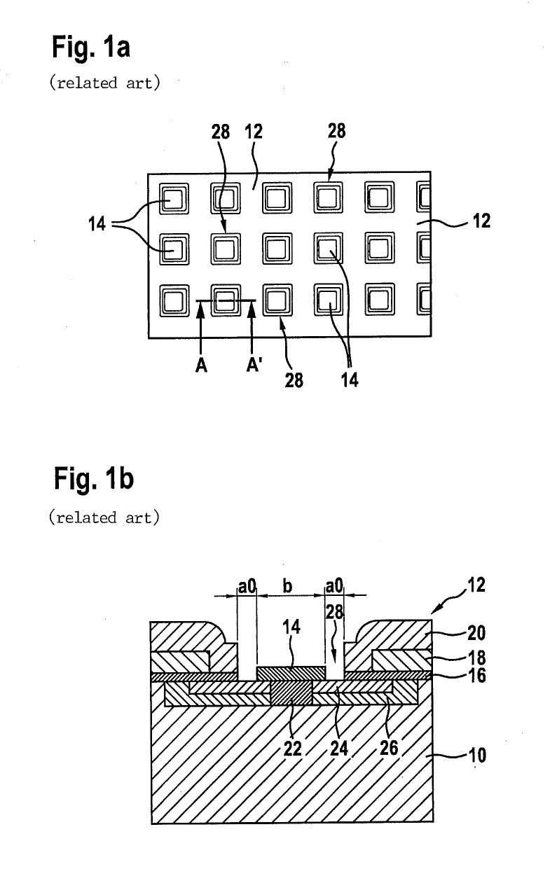

### DETAILED DESCRIPTION OF THE INVENTION

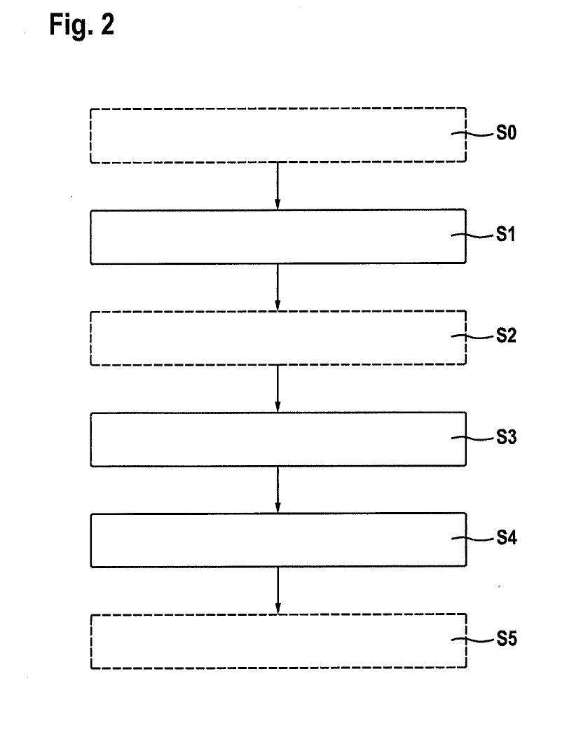

FIG. 2 shows a flow chart to illustrate a first specific embodiment of the method for forming a contact on a semiconductor substrate.

In an optional method step S0, structures which later cooperate with the at least one formed contact may be created on the semiconductor substrate. For example, at least one implantation may be introduced into the semiconductor substrate. At least one material may also be deposited on the semiconductor substrate. In particular, at least one gate stack structure and/or at least one gate stack substructure may be formed on the semiconductor substrate. For this purpose, a gate oxidation may be carried out and/or a gate metallization, such as polysilicon, may be deposited.

Moreover, an insulating layer may be formed in method step S0 on at least one partial outer side of the outer side of the semiconductor substrate and/or on a layer which is applied to the semiconductor substrate. For example, at least one silicon oxide layer and/or one silicon nitride layer may be formed as the insulating layer. In particular, the insulating layer may include a high temperature oxide which is formed at a temperature between 600° C. and 1000° C. Furthermore, DCS and nitrogen oxide (N₂O) may be used as starting materials for forming the insulating layer. However, instead of the examples listed here, other materials may also be used for forming the insulating layer.

At least one gate stack structure and/or at least one gate stack substructure may be covered by the insulating layer. If at least one gate stack substructure is covered by the insulating layer, at least regions of the insulating layer are also usable as a subunit of the gate stack structure formed therewith. This multifunctionality of the insulating layer allows materials and/or method steps to be saved.

In method step S0, at least one partial area of the outer side of the semiconductor substrate and/or of the layer which is applied to the semiconductor substrate at at least one point of the at least one contact to be formed may be exposed from the previously formed insulating layer. It is possible to carry out conventional structuring steps for structuring the insulating layer.

In a method step S1, at least one metal is applied to at least one exposed partial area of the outer side of the semiconductor substrate and/or of the layer which is applied to the semiconductor substrate. When the at least one metal is applied, at least one edge region of the insulating layer, which surrounds the (formerly exposed) partial area, is at least partially covered by the at least one metal. The at least one metal may thus be applied comparatively coarsely. For example, nickel, titanium, aluminum, tantalum and/or tungsten may be applied as the at least one metal. To apply the at least one metal, the same may be sputtered onto the, in particular unmasked, semiconductor substrate. Method step S1 is thus carried out easily and quickly.

In an optional method step S2, the at least one applied metal may be coarsely structured. For example, a lithography step and wet-chemical etching may be carried out for this purpose. It is pointed out that method step S2 is not necessary for carrying out the method. This structuring step may be dispensed with in particular if all structures on the outer side to be protected from a reaction with the at least one metal are covered by the insulating layer. If method step S2 is carried out, coarse structuring of the at least one metal is sufficient. It is pointed out in particular that it is not necessary to expose the at least one edge region of the insulating layer from the at least one metal.

In a method step S3, which is carried out after method step S1 or S2, the semiconductor substrate is heated together with the at least one metal which is applied to the at least one partial area and the at least one edge region. The heating process prompts a reaction of the at least one metal which is applied to the at least one partial area with at least one semiconductor material of the at least one partial area to form a semiconductor-metal material (as the end material or a further processing material of at least one contact).

During the heating process, the semiconductor substrate may be heated to a temperature of at least 600° C. For example, the semiconductor substrate is heated to a temperature around 1000° C. for a duration of approximately 2 minutes. The temperature to be maintained during heating and the duration of this method step may be selected relatively freely, taking the at least one applied metal and/or the semiconductor material of the at least one partial area into consideration. The semiconductor substrate may be heated together with the at least one metal which is applied to the at least one partial area and to the at least one edge region by a rapid thermal annealing process step, for example.

During the heating process, for example, the at least one metal and the at least one semiconductor material may react to form the end material of what will later be the at least one contact. As an alternative, a further processing material may also be created, which is the result of the reaction of the at least one metal and the at least one semiconductor material with each other, which in a further method step (not described) reacts with at least one other substance to form the end material of the at least one contact. The resistive behavior of the at least one contact, which is formed at this point in time or later, may be created by the heating process. If this is desired, a temperature which is sufficiently high for creating the resistive behavior may be adjusted during the heating process. An alternative procedure to this is described hereafter.

During the heating process of the semiconductor substrate together with the at least one metal which is applied to the at least one partial area and the at least one edge region, the at least one metal may partially react with the insulating layer. However, the consumption of the insulating material of the insulating layer is generally negligibly low. If the insulating layer is to also carry out a function after the at least one contact has been formed, the consumption may be slightly compensated for by creating an insulating layer having a marginally increased thickness, such as by 40 nm.

An etching step is carried out after method step S3 as method step S4. This takes place using an etching material having a higher etching rate for the at least one metal than for the semiconductor-metal material. The etching step carried out in method step S4 may in particular be an isotropic etching step. It is pointed out that a plurality of etching materials may be used for carrying out method step S4. The selection of the etching material may be selected relatively freely, taking the at least one metal and the semiconductor-metal material into consideration. For example, the nickel which is used as the at least one metal may be easily removed in method step S4 using a mixture of phosphoric and nitric acid. Residual traces of the at least one metal may remain on an outer surface of the insulating layer. These residual traces may in particular also be compounds made from the at least one metal and the insulating material of the insulating layer.

The semiconductor substrate manufactured with the aid of the above-described method steps may be further processed with the aid of known methods.

The at least one contact formed with the aid of the above-described method may be formed at a distance from at least one gate stack structure which is smaller than 10 nm, the distance being oriented parallel to the semiconductor surface on which the at least one contact is implemented. The distance may in particular be smaller than 5 nm. With the aid of the above-described method, it is thus possible to implement an arrangement of the at least one formed contact on at least one gate stack structure which ensures an advantageously high cell density on the semiconductor surface.

In one particularly advantageous specific embodiment, at least one source contact is formed as the at least one contact. The source contact may be formed on a silicon carbide substrate, for example. In this way, a power semiconductor (MOSFET) may be formed with the aid of the method, without a structuring step for structuring the source contact. This may thus also be referred to as a self-aligned manufacturing process of the power semiconductor which is configured with source contacts.

However, the usability of the method described here is not limited to a power semiconductor having source contacts.

Instead, a plurality of electrical components is producible with the aid of the method described here.

In one advantageous refinement of the method, the at least one deposited metal is heated during method step S3 to a comparatively low temperature between 500° C. and 800° C. in a first furnace process. As a result of this first furnace process, the at least one metal may react with the semiconductor material, such as silicon carbide, without the reaction product becoming resistive/easily conductive. The low temperature allows the likelihood of a reaction between the at least one metal and the insulating material of the insulating layer to be reduced. Thereafter, the remaining at least one metal may be removed in method step S4. As an optional method step S5, a second furnace process may then be carried out to ensure sufficiently good conductivity of the at least one contact with the aid of a higher temperature. The advantage of this procedure is a lower degradation of the insulating material of the insulating layer during method step S3 while maintaining the low contact resistance levels.

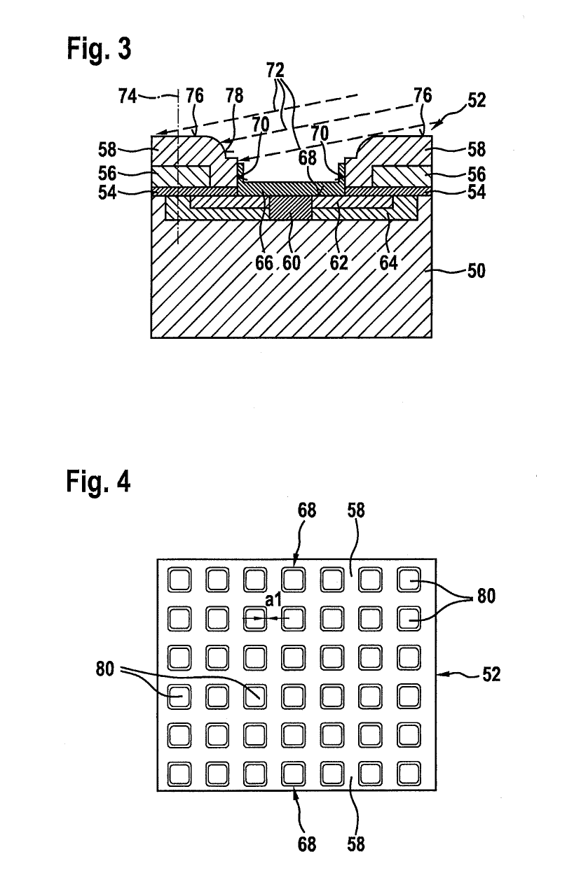

FIG. 3 shows a schematic cross section through a semiconductor substrate to explain a second specific embodiment of the method for forming a contact on a semiconductor substrate.

A semiconductor substrate 50 having a gate stack structure 52 formed thereon is shown schematically in FIG. 3. Semiconductor substrate 50 may be a silicon carbide substrate, for example. However, the ability to carry out the method described hereafter is not limited to the use of a silicon carbide substrate as semiconductor substrate 50.

A gate oxide layer 54 is deposited onto semiconductor substrate 50 to form gate stack structure 52. Gate oxide layer 54 is partially covered by a gate metallization layer 56, e.g., made of polysilicon. An insulating layer 58, such as a silicon oxide layer and/or silicon oxide layer, is applied to gate layers 54 and 56. However, the creation of gate stack structure 52 from layers 54 through 58 shall only be interpreted by way of example.

In addition to gate stack structure 52, implantations 60 through 64 may be introduced into semiconductor substrate 50, with the aid of which an electrical connection may be created between gate stack structure 52 and a contact formed with the aid of the method described hereafter. The concentrations and ions of implantations 60 through 64 are selectable with great design freedom.

The method includes method step S1 already described above, in which at least one metal, such as nickel, titanium, aluminum, tantalum and/or tungsten, is deposited. In this way, at least one partial area 68/opening of layers 54 through 58, which is (still) exposed or has been exposed, is covered by at least one metal 66. The at least one metal 66 may be coarsely applied in such a way that at least one edge region 70 of insulating layer 58 surrounding at least one partial area 68 is at least partially covered by the at least one metal 66. Method step S2, which was already described above, may be optionally carried out thereafter.

After method step S1 or S2 (i.e., between the application of the at least one metal 66 and the later heating of semiconductor substrate 50), in the specific embodiment of the method described here an ion beam etching step is carried out in an etching direction 72 which is inclined relative to an axis 74/wafer vertical which is oriented perpendicularly to an outer side of semiconductor substrate 50 having semiconductor structure 52 formed thereon. Etching direction 72 may be oriented at an incline relative to axis 74/wafer vertical by an angle between 5° and 88°, preferably between 30° and 85°, more preferably between 60° and 80°. The ability to carry out the method step shown in FIG. 3 is not limited to one particular angle. This may also be described as ion beam etching with a strong tilt between the ion beam oriented along etching direction 72 and axis 74/wafer vertical. The at least one metal 66 may be easily coarsely removed from gate stack structure 52 with the aid of such an ion beam etching process/ion beam etching step.

However, during the ion beam etching process/ion beam etching step, the at least one metal 66 is removed only from at least one top side 76 of gate stack structure 52 directed away from semiconductor substrate 50 and from at least one side wall region 78 of gate stack structure 52 adjoining top side 76. In contrast, gate stack structure 52 acts as a shield with respect to partial area 68 and edge region 70 of insulating layer 58 surrounding partial area 68, which is why the at least one metal 66 is not/barely removed from partial area 68 and edge region 70 of insulating layer 58. This may be described in such a way that the at least one metal 66 is not, or only partially, removed from at least one partial area 68, which may be referred to as the base of an opening in gate stack structure 52, and the at least one adjoining edge region 70.

With the aid of the method step described in FIG. 3, the at least one metal 66 may be removed from at least one top side 76 and the at least one adjoining side wall region 78 of gate stack structure 52 already prior to method step S3/the contact alloying. This causes (almost) no residual traces of the at least one metal 66 to remain on insulating layer 52 after subsequently carried out method steps S3 and S4. In this way, it is possible to ensure improved adhesion of the bond metallization and increased reliability of the semiconductor device manufactured with the aid of the method.

Reference is made to the above description with respect to subsequently executable method steps S3 and S4.

FIG. 4 shows a schematic top view onto one specific embodiment of the semiconductor device.

The semiconductor device shown schematically in FIG. 4 includes a semiconductor substrate (not shown) and at least one contact 80, which is situated on and/or in at least one partial area 68 of an outer side of the semiconductor substrate and/or of a layer applied to the semiconductor substrate and which is formed of a semiconductor-metal material. Moreover, the semiconductor device includes a gate stack structure 52 on the outer side of the semiconductor substrate and/or of a layer which is applied to the semiconductor substrate, the structure adjoining at least one contact 80. Reference is made to the above description with respect to the materials of the semiconductor substrate, gate stack structure 52 and the at least one contact 80.

A distance a1 between the at least one gate stack structure 52 and at least one of contacts 80 is smaller than 10 nm, the distance being oriented parallel to the semiconductor surface having at least one contact 80 formed thereon. Distance a1 between the at least one gate stack structure 52 and at least one of contacts 80 may in particular be smaller than 5 nm. Based on the advantageously small distance a1, it is detectable that the semiconductor device is manufactured with the aid of one specific embodiment of the above-described method. Reference is made to the description above with respect to the advantages which are ensured by the semiconductor device.

In the illustrated specific embodiment, the at least one contact 80 is surrounded by the at least one gate stack structure 52 at distance a1 of smaller than 10 nm/5 nm. This may also be described in such a way that the at least one contact 80 is formed in an opening in the at least one gate stack structure 52 at a distance a1 of smaller than 10 nm/5 nm.

The manufacture of the semiconductor device with the aid of the above-described method may also be detectable based on the fact that the at least one contact 80 is surrounded by an insulating layer 58 which at least partially covers gate stack structure 52 or a gate stack substructure, the insulating layer including residual traces of nickel, titanium, aluminum, tantalum and/or tungsten on its outer surface. The residual traces may also be attributable to a bond of the metals listed here with the insulating material of insulating layer 58.

At least one contact 80 is a source contact in the shown specific embodiment. However, the semiconductor device represented with the aid of FIG. 4 is not limited to being configured with a source contact as the at least one contact 80.

1-15. (canceled)

16. A method for forming a contact on a semiconductor substrate, comprising:
applying at least one metal to at least one exposed partial area of at least one of an outer side of the semiconductor substrate and a layer which is applied to the semiconductor substrate, the partial area being surrounded by at least one edge region of an insulating layer, and the at least one edge region of the insulating layer being at least partially covered by the at least one metal;
heating the semiconductor substrate together with the at least one metal applied to the at least one partial area and the at least one edge region to a temperature of approximately 1000° C., the duration of the heating being selected as a function of at least one of the applied metal and the semiconductor material of the at least one partial area, whereby the at least one metal which is applied to the at least one partial area reacts with at least one semiconductor material of the at least one partial area to form a semiconductor-metal material as one of the end material of the contact or a further processing material of the contact; and
etching using an etching material having a higher etching rate for the at least one metal than for the semiconductor-metal material.

17. The method as recited in claim 16, wherein the contact is formed at a distance less than 10 nm from at least one gate stack structure.

18. The method as recited in claim 16, wherein at least one ion beam etching step is carried out between the application of the at least one metal and the heating of the semiconductor substrate, in an etching direction which is inclined relative to an axis oriented perpendicularly to the outer side of the semiconductor substrate.

19. The method as recited in claim 18, wherein at least one of nickel, titanium, aluminum, tantalum and tungsten is applied as the at least one metal.

20. The method as recited in claim 16, wherein, prior to the application of the at least one metal, the insulating layer is formed on at least one partial outer side of at least one of the outer side of the semiconductor substrate and the layer which is applied to the semiconductor substrate, and the at least one partial area of the at least one of the outer side of the semiconductor substrate and the layer applied to the semiconductor substrate is exposed at a point corresponding to a point of the contact.

21. The method as recited in claim 20, wherein at least one of a silicon oxide layer and a silicon nitride layer is formed as the insulating layer.

22. The method as recited in claim 20, wherein at least one of a gate stack structure and a gate stack substructure is covered by the insulating layer.

23. The method as recited in claim 22, wherein the metal and the insulating layer react with each other during the heating process.

24. The method as recited in claim 23, wherein an isotropic etching step is carried out as the etching step using the etching material having the higher etching rate for the at least one metal than for the semiconductor-metal material.

25. The method as recited in claim 20, wherein at least one source contact is formed as the contact.

26. A semiconductor device, including:
a semiconductor substrate;
at least one contact which is (i) situated at least one of on and in at least one partial area of at least one of an outer side of the semiconductor substrate and a layer applied to the semiconductor substrate, and (ii) formed of a semiconductor-metal material; and
a gate stack structure which is (i) situated on the outer side of the at least one of the semiconductor substrate and the layer applied to the semiconductor substrate, and (ii) adjoins the at least one contact;
wherein a distance between the gate stack structure and the at least one contact is less than 10 nm.

27. The semiconductor device as recited in claim 26,wherein the distance between the gate stack structure and the at least one contact is less than 5 nm.

28. The semiconductor device as recited in claim 26, wherein the at least one contact is surrounded by the gate stack structure at a distance of less than 10 nm.

29. The semiconductor device as recited in claim 28, wherein the at least one contact is a source contact.

30. The semiconductor device as recited in claim 26, wherein the at least one contact is surrounded by an insulating layer which at least partially covers one of the gate stack structure or a gate stack substructure, wherein an outer surface of the insulating layer includes at least one of nickel, titanium, aluminum, tantalum and tungsten.
